(19) United States
(12) Patent Application Publication
(10) Pub. No.: US 2005/0068272 A1
(43) Pub. Date: Mar. 31, 2005

(54) Electroluminescent display device and manufacturing method of the same

(75) Inventor: Kiyoshi Yoneda, Motosu-gun (JP)

Correspondence Address: MORRISON & FOERSTER LLP, 1650 TYSONS BOULEVARD, SUITE 300, MCLEAN, VA, 22102, US

(73) Assignee: Sanyo Electric Co., Ltd., Osaka (JP)

(21) Appl. No.: 10/674,827

(22) Filed: Oct. 1, 2003

(30) Foreign Application Priority Data
Oct. 1, 2002 (JP) 2002-288502
Mar. 3, 2003 (JP) 2003-55334

(51) Int. Cl. G09G 3/30; G09G 3/36

(52) U.S. Cl. 345/76; 345/92

(57) ABSTRACT

A pixel selecting TFT is made of a polysilicon TFT, in which a gate insulating layer is formed on an active layer made of a polysilicon layer formed on a transparent insulating substrate made of a glass substrate or the like, and two gates and extend from a gate signal line. A driving TFT is made of an amorphous silicon TFT, in which a gate insulating layer is formed on an active layer made of an amorphous silicon layer formed on the transparent insulating substrate, and a gate made of a Cr layer, a Mo layer or the like is formed on the gate insulating layer.

### BACKGROUND OF THE INVENTION

1. Field of the Invention

The invention relates to an electroluminescent display device and a manufacturing method thereof, particularly to an electroluminescent display device having a pixel selecting thin film transistor and a driving thin film transistor for current-driving of an electroluminescent element in each of pixels and a manufacturing method thereof.

2. Description of the Related Art

In recent years, electroluminescent (hereafter, referred to as EL) display devices with an El element have been receiving an attention as a new display device substituting for a CRT or an LCD. Particularly, developments are directed to an EL display device having a thin film transistor (hereinafter, referred to as “TFT”) as a switching element driving the EL element.

FIG. 4 shows an equivalent circuit diagram of a pixel in an organic EL display panel. In an actual organic EL display panel, a plurality of the pixels is disposed in a matrix form.

A gate signal line 50 for supplying a gate signal Gn and a drain signal line 60 for supplying a display signal Dm cross each other.

Adjacent a cross section of those signal lines, an organic EL element 70, a driving TFT 80 for driving the organic EL element 70, and a pixel selecting TFT 10 for selecting a pixel are disposed.

A positive power supply voltage PVdd is supplied from a power supply line 90 to a source of the driving TFT 80. A drain of the driving TFT 80 is connected to an anode 71 of the organic EL element 70.

The gate signal line 50 is connected to a gate of the pixel selecting TFT 10, supplying the gate signal Gn thereto. The drain signal line 60 is connected to a drain 10d of the pixel selecting TFT 10, supplying the display signal Dm thereto. A source 10s of the pixel selecting TFT 10 is connected to a gate of the driving TFT 80. The gate signal Gn is outputted from a vertical driving circuit which is not shown. The display signal Dm is outputted from a horizontal driving circuit which is not shown.

The organic EL element 70 includes an anode 71, a cathode 72, and an emitting layer (not shown) formed between the anode 71 and the cathode 72. A negative power supply voltage CV is supplied to the cathode 72.

A storage capacitor Cs is connected to the gate of the driving TFT 80. The storage capacitor Cs is provided for retaining an electric charge corresponding to the display signal Dm for a pixel for one field period.

Operation of the EL display device having the above configuration will be described. When the gate signal Gn turns high level for one horizontal period, the pixel selecting TFT 10 turns on. Then, the display signal Dm is applied to the gate of the driving TFT 80 from the drain signal line 60 through the pixel selecting TFT 10.

Conductance of the driving TFT 80 changes in response to the display signal Dm supplied to the gate, a driving current corresponding to the change is supplied to the organic EL element 70 through the driving TFT 80, and the organic EL element 70 emits light. When the driving TFT 80 is in an off state in response to the display signal Dm supplied to the gate thereof, an electric current does not flow through the driving TFT 80 so that the organic EL element 70 also stops emitting light.

Both active layers of the pixel selecting TFT 10 and the driving TFT 80 are made of a polysilicon layer.

Japanese Patent Application Publication No. 2002-175029 describes one example of a conventional device. The pixel selecting TFT 10 needs to have low on-resistance since it needs to switch at high speed in response to the gate signal Gn. On the contrary, the driving TFT 80 preferably has high on-resistance since it needs to limit an electric current flowing to the organic EL element 70. Therefore, conventionally, the pixel selecting TFT 10 is designed to have a large channel width, and the driving TFT 80 is designed to have a long channel length. However, this causes a problem of making a pattern size of the driving TFT 80 large.

### SUMMARY OF THE INVENTION

The invention provides an electroluminescent display device that includes a plurality of pixels, an electroluminescent element provided in each of the pixels, a pixel selecting transistor provided in each of the pixels and selecting the corresponding pixel in response to a gate signal, and a driving transistor provided in each of the pixels and supplying an electric current to the corresponding electroluminescent element in response to a display signal supplied through the corresponding pixel selecting transistor. The pixel selecting transistor comprises an active layer made of polysilicon, and the driving transistor comprises an active layer made of amorphous silicon.

The invention also provides an electroluminescent display device that includes a plurality of pixels, an electroluminescent element provided in each of the pixels, a pixel selecting thin film transistor provided in each of the pixels and selecting the corresponding pixel in response to a gate signal, and a driving thin film transistor provided in each of the pixels and supplying an electric current to the corresponding electroluminescent element in response to a display signal supplied through the corresponding pixel selecting thin film transistor. A carrier mobility of the driving thin film transistor is lower than a carrier mobility of the pixel selecting thin film transistor.

The invention provides a manufacturing method of an electroluminescent display device including a substrate, a pixel selecting transistor formed on the substrate and a driving transistor formed on the substrate and driving an electroluminescent element. The method includes forming an amorphous silicon layer on the whole surface of the substrate, irradiating part of the amorphous silicon layer by a laser to grow crystallites, and patterning the irradiated part of the amorphous silicon layer to form an active layer of the pixel selecting transistor and patterning the amorphous silicon layer that is not irradiated by the laser to form an active layer of the driving transistor.

The invention also provides a manufacturing method of an electroluminescent display device including a substrate, a plurality of first thin film transistors for selecting a corresponding pixel and a plurality of second thin film transistors for driving a corresponding electroluminescent element. The method includes forming an amorphous silicon layer on the whole surface of the substrate, providing a mask having openings corresponding to the first thin film transistors, irradiating portions of the amorphous silicon layer through a set of the openings by a laser to grow crystallites, and repeating the irradiating of the amorphous silicon layer through another set of the openings.

### BRIEF DESCRIPTION OF THE DRAWINGS

FIG. 1 is a plan view of an electroluminescent display device of an electroluminescent display device of a first embodiment of the invention.

FIGS. 2A and 2B are cross-sectional views of a pixel selecting TFT and a driving TFT of FIG. 1.

FIGS. 3A, 3B, and 3C correctively show a manufacturing method of the electroluminescent display device of the first embodiment of the invention.

FIG. 4 is a circuit diagram of a conventional electroluminescent display device.

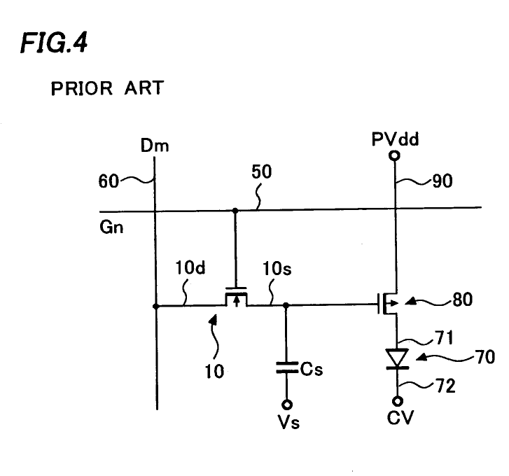

### DETAILED DESCRIPTION OF THE INVENTION

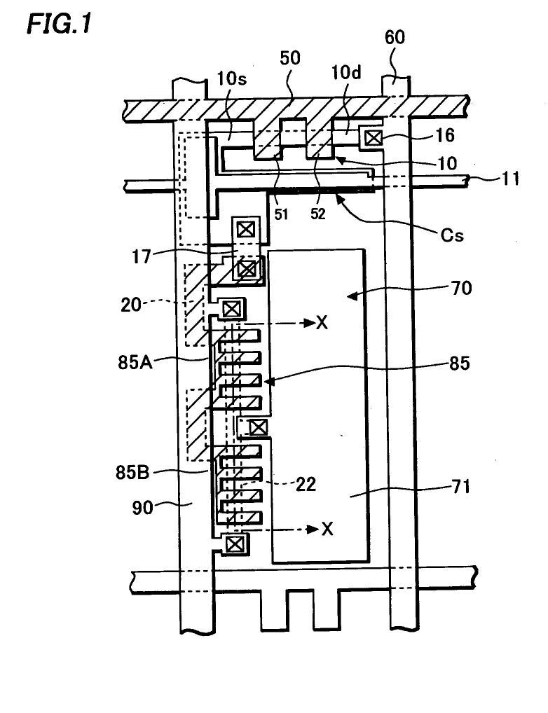

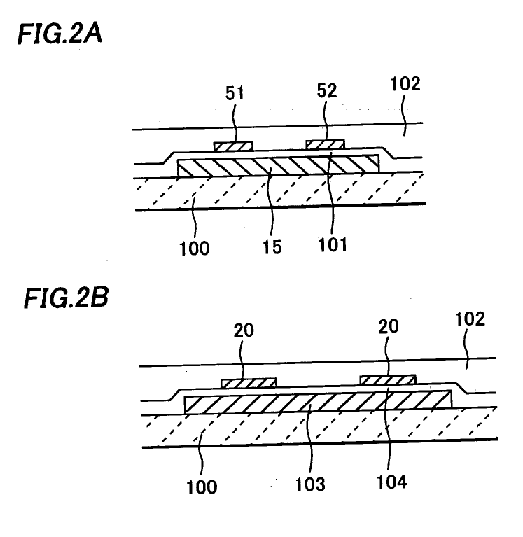

Embodiments of the invention will be described with reference to the drawings in detail. An EL display device of a first embodiment of this invention will be described with reference to FIGS. 1, 2A and 2B. FIG. 1 is a pattern view of a pixel of the EL display device of the first embodiment, and FIGS. 2A and 2B are cross-sectional views of a pixel selecting TFT 10 and a driving TFT 85 shown in FIG. 1. In an actual organic EL display panel, a plurality of the pixels is disposed in a matrix form. In the embodiment, the pixel selecting TFT 10 and the driving TFT 85 include a polysilicon TFT and an amorphous silicon TFT, respectivelly.

A pixel configuration will be described in detail hereafter. A gate signal line 50 for supplying a gate signal Gn is disposed in a row direction, and a drain signal line 60 for supplying a display signal Dm is disposed in a column direction. Those lines cross three-dimensionally without contacting each other. The gate signal line 50 is made of a Cr (chromium) layer, a Mo (molybdenum) layer, etc. The drain signal line 60 is made of an aluminum layer etc, being formed on the gate signal line 50.

The pixel selecting TFT 10 includes a polysilicon TFT. This pixel selecting TFT 10 has a double gate structure in which a gate insulating layer 101 is formed on an active layer 15 made of an polysilicon layer formed on a transparent insulating substrate 100 made of a glass, etc, and two gates 51 and 52 both extending from the gate signal line 50 are formed on the gate insulating layer 101. On the gates 51 and 52, an interlayer insulating layer 102 is formed (FIG. 2A).

A drain 10d of the pixel selecting TFT 10 is connected to the drain signal line 60 through the contact 16. The polysilicon layer forming a source 10s of the pixel selecting TFT 10 extends to a storage capacitor region, and overlaps an upper storage capacitor line 11 with a capacitor insulating film therebetween, forming a storage capacitor Cs at this overlapping portion.

The polysilicon layer extending from the source 10s of the pixel selecting TFT 10 is connected to a gate 20 of the driving TFT 85 through an aluminum wiring 17.

The driving TFT 85 includes an amorphous silicon TFT. In the driving TFT 85, a gate insulating layer 104 is formed on an active layer 103 made of an amorphous silicon layer formed on the transparent insulating substrate 100, and a gate 20 made of a Cr layer, a Mo layer or the like is formed on the gate insulating layer 104. The interlayer insulating layer 102 is formed on the gate 20. The gate insulating layer 104 can be formed in a same step as the step where the gate insulating layer 101 of the pixel selecting TFT 10 is formed (FIG. 2B).

The driving TFT 85 includes two parallel transistors 85A and 85B which share the gate 20. Sources of the parallel transistors 85A and 85B are connected to a power supply line 90 supplied with a positive power supply voltage PVdd through a contact. A common drain of the parallel transistors 85A and 85B is connected to an anode 71 of an organic EL element 70 through a contact.

For forming the pixel selecting TFT 10 of the polysilicon TFT and the driving TFT 85 of the amorphous silicon TFT, the active layer 15 of the pixel selecting TFT 10 needs to be formed of a polysilicon layer, and the active layer 103 of the driving TFT 85 needs to be formed of an amorphous silicon layer. A manufacturing method thereof will be described hereafter.

First, an amorphous silicon layer is formed on the whole surface of the insulating substrate 100 by a CVD (chemical vapor deposition) method, a point of a region of the amorphous silicon layer to become an active layer of the pixel selecting TFT 10 is irradiated by laser beams, and the laser beam scans the entire region to become the active layer.

The seed crystals formed in the first irradiated spot grows in a scanning direction so that the amorphous silicon in the region turn into polysilicon. On the contrary,

the region to become an active layer 103 of the driving TFT 85 is not irradiated by the laser and remains as amorphous silicon. Then, patterns of the active layer 15 of the pixel selecting TFT 10 and the active layer 103 of the driving TFT 85 are made by an ordinary photolithography process.

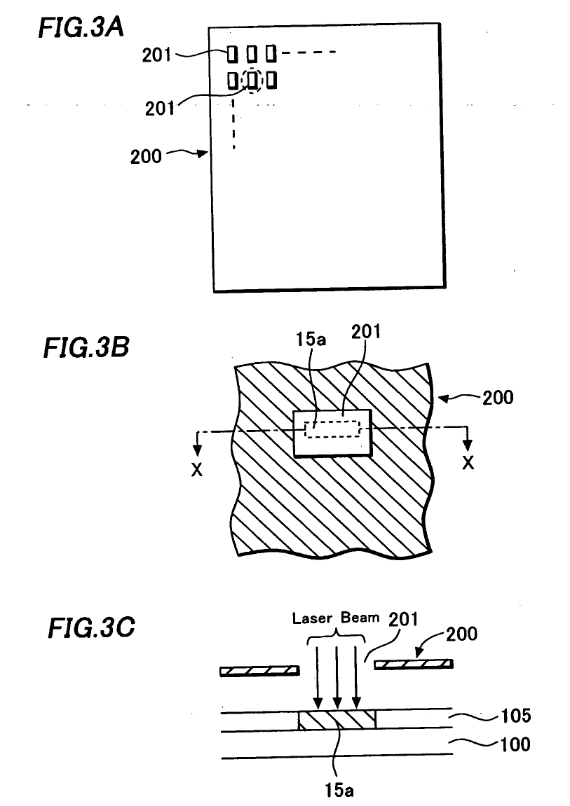

Alternatively, a mask provided with openings can be used so as to irradiate only the region corresponding to the active layer of the pixel selecting TFT 10. FIGS. 3A, 3B, 3C are views showing such a manufacturing method of the organic EL display device. FIG. 3A shows a configuration of a mask 200 for photolithography. The mask 200 covers a sheet of organic EL display panel, and has openings 201 corresponding to regions to become the active layer 15a of the pixel selecting TFT 10 for each of the pixels.

FIG. 3B is an enlarged view of one of the openings 201 and its surroundings shown in FIG. 3A (a region enclosed in a dotted line). FIG. 3C is a cross-sectional view of FIG. 3B along line X-X. The mask 200 is placed to cover the insulating substrate 100 so that the openings 201 are positioned right above the corresponding regions to become the active layer 15a of the pixel selecting TFT 10. The amorphous silicon layer 105 has been already deposited by the CVD method on the whole surface of the insulating substrate 100.

Then, laser beams are directed to the insulating substrate 100 starting from the upper side of the mask 200. The laser beams are directed to the amorphous silicon layer 105 on the insulating substrate 100 through the opening 201 of the mask 200 for a predetermined time. The irradiated amorphous silicon is dissolved, and then crystallized in a cooling process. Accordingly, the amorphous silicon in the irradiated increases its grain size or is converted into polysilicon. On the contrary, the laser beams are prevented from reaching the region to become the active layer 103 of the driving TFT 85 by the mask 200 so that the region remains amorphous.

Thus, one-time irradiation of laser beams to a predetermined region of the sheet of organic EL display panels using the mask 200 is performed. In this manufacturing of the organic EL display device, a plurality of organic EL display panels is disposed in a matrix on a sheet of the insulating substrate 100. Here, the one-time irradiation of laser beams using the mask 200 may be sequentially performed to each of the organic EL display panels by a step and repeat method. That is, the one-time irradiation of laser beams using the mask 200 is performed to one organic EL display panel, and is then performed to the adjacent organic EL display panel. This process is repeated. After all the organic EL display panels are irradiated, pattern formation of the active layer 15 of the pixel selecting TFT 10 and the active layer 103 of the driving TFT 85 is performed by the ordinary photolithography process.

In this embodiment, the pixel selecting TFT 10, which needs to have low on-resistance for switching at high speed, relies on a polysilicon active layer, and the driving TFT 85, which needs to have high on-resistance, relies on an amorphous silicon active layer. This enables optimal designing of each of the TFTs so as to achieve required device characteristics. Particularly, since the carrier mobility of the driving TFT 85 is lower than that of the pixel selecting TFT 10, an electric current flowing to the organic EL element 70 can be limited even if the channel length of the driving TFT 85 is short. Therefore, the size of the TFT is smaller than that of a conventional design.

Next, a second embodiment of the invention will be described. In this embodiment, the pixel selecting TFT 10 and the driving TFT 85 each include a polysilicon TFT, and the grain size of the driving TFT 85 is smaller than that of the pixel selecting TFT 10. That is, the active layer 15 of the pixel selecting TFT 10 is formed of a polysilicon layer, and the active layer 103 of the driving TFT 85 is also formed of a polysilicon layer. The polysilicon grain size of the active layer 103 of the driving TFT 85 is smaller than that of the active layer 15 of the pixel selecting TFT 10. Other configurations are the same as those in the first embodiment.

The carrier mobility of the polysilicon TFT increases when the polysilicon grain size increases. Therefore, in this embodiment, the carrier mobility of the driving TFT 85 is lower than the carrier mobility of the pixel selecting TFT 10. This enables limiting of an electric current flowing to the organic EL element 70 even if the channel length of the driving TFT 85 is short, similarly to the first embodiment, thereby reducing the size of the TFT.

To form the pixel selecting TFT 10 and the driving TFT 85 of this embodiment, the power of laser may be changed when the amorphous silicon layer, which is formed on the whole surface of the insulating substrate 100 by the CVD method, is crystallized by irradiation of the laser beams (for example, excimer laser). Other methods may also be used to form the TFTs of this embodiment. For example, a pulse cycle of a pulse laser may be changes, an amount of overlapping pulse lasers during scanning by pulse lasers may be changed, or the cross-section shape of the laser beam (spot beam, line beam) may be changed.

The driving TFT 85 includes the parallel transistors 85A and 85B in the embodiments. This is to maintain driving of one transistor even if another transistor is defective. Thus, the parallel transistors do not have to be employed.

Furthermore, although the pixel selecting TFT 10 has a double gate structure in the embodiments, a single gate structure may be employed.

1. An electroluminescent display device, comprising:
a plurality of pixels;
an electroluminescent element provided in each of the pixels;
a pixel selecting transistor provided in each of the pixels and selecting the corresponding pixel in response to a gate signal; and
a driving transistor provided in each of the pixels and supplying an electric current to the corresponding electroluminescent element in response to a display signal supplied through the corresponding pixel selecting transistor,
wherein the pixel selecting transistor comprises an active layer made of polysilicon, and the driving transistor comprises an active layer made of amorphous silicon.

2. An electroluminescent display device, comprising:
a plurality of pixels;
an electroluminescent element provided in each of the pixels;
a pixel selecting thin film transistor provided in each of the pixels and selecting the corresponding pixel in response to a gate signal; and
a driving thin film transistor provided in each of the pixels and supplying an electric current to the corresponding electroluminescent element in response to a display signal supplied through the corresponding pixel selecting thin film transistor,
wherein a carrier mobility of the driving thin film transistor is lower than a carrier mobility of the pixel selecting thin film transistor.

3. The electroluminescent display device of claim 2, wherein the pixel selecting thin film transistor comprises a first polysilicon active layer and the driving thin film transistor comprises a second polysilicon active layer.

4. The electroluminescent display device of claim 3, wherein a gain size of the first polysilicon active layer is larger than a grain size of the second polysilicon active layer.

5. A manufacturing method of an electroluminescent display device comprising a substrate, a pixel selecting transistor formed on the substrate and a driving transistor formed on the substrate and driving an electroluminescent element, the method comprising:
forming an amorphous silicon layer on a whole surface of the substrate;
irradiating part of the amorphous silicon layer by a laser to grow crystallites; and
patterning the irradiated part of the amorphous silicon layer to form an active layer of the pixel selecting transistor and patterning the amorphous silicon layer that is not irradiated by the laser to form an active layer of the driving transistor.

6. The manufacturing method of the electroluminescent display device of claim 5, wherein the electroluminescent display device further comprises at least one additional pixel selecting transistor, the method further comprises providing a mask having openings corresponding to the pixel selecting transistors, and the irradiating by the laser comprises irradiating the amorphous silicon layer through the openings at one time.

7. The manufacturing method of the electroluminescent display device of claim 5, wherein the electroluminescent display device further comprises a plurality of pixel selecting transistors, the method further comprises providing a mask having openings corresponding to the pixel selecting transistors, and the irradiating by the laser comprises irradiating the amorphous silicon layer through a set of the openings at one time.

8. The manufacturing method of the electroluminescent display device of claim 7, wherein the irradiating by the laser is repeated by irradiation through another set of the openings.

9. A manufacturing method of an electroluminescent display device comprising a substrate, a plurality of first thin film transistors for selecting a corresponding pixel and a plurality of second thin film transistors for driving a corresponding electroluminescent element, the method comprising:
forming an amorphous silicon layer on a whole surface of the substrate;
providing a mask having openings corresponding to the first thin film transistors;
irradiating portions of the amorphous silicon layer through a set of the openings by a laser to grow crystallites; and
repeating the irradiating of the amorphous silicon layer through another set of the openings.
